(19) United States
(12) Patent Application Publication
(10) Pub. No.: US 2008/0012740 A1
(43) Pub. Date: Jan. 17, 2008

(54) Source-aware non-uniform information transmission with minimum distortion

(75) Inventors: Tongtong Li, Okemos, MI (US); Huahui Wang, Wheeling, IL (US); Qi Ling, East Lansing, MI (US)

Correspondence Address: HARNESS, DICKEY & PIERCE, P.L.C., P.O. BOX 828, BLOOMFIELD HILLS, MI, 48303, US

(73) Assignee: Board of Trustees of Michigan State University, East Lansing, MI (US)

(21) Appl. No.: 11/825,132

(22) Filed: Jul. 3, 2007

Related U.S. Application Data
(60) Provisional application No. 60/819,004, filed on Jul. 6, 2006.

(51) Int. Cl. H03M 7/00

(52) U.S. Cl. 341/107

(57) ABSTRACT

A method is provided for transmitting information in a data communication system. The method includes: receiving a codeword having a plurality of bits; mapping more significant bits of the codeword to bit locations of a symbol in a constellation with lower error probabilities, where the constellation represents a modulation scheme; modulating the symbol in accordance with the modulation scheme; and transmitting the symbol from a transmitter in the data communication system.

### CROSS-REFERENCE TO RELATED APPLICATIONS

This application claims the benefit of U.S. Provisional Application No. 60/819,004, filed on Jul. 6, 2006. The disclosure of the above application is incorporated herein by reference.

### FIELD

The present disclosure relates to a source-aware information transmission scheme that simultaneously minimizes bit error rate and distortion.

### BACKGROUND

Given a source with rate R bits/second and a channel with capacity C bits/second, Shannon's well known channel capacity theorem, says that if R<C, then there exists a combination of source and channel coders such that the source can be communicated over the channel with fidelity arbitrarily close to perfect. This theorem essentially implies that the source coding and channel coding are fundamentally separable without loss of performance for the overall system.

Following the “separation principle”, in most modern communication systems, source coding and channel coding are treated independently. In other words, source representation is designed disjointly from information transmission. After A/D conversion of analog source signals, the bit streams are then uniformly encoded and mapped to symbols prior to transmission. Uniform bit-error-rate (BER) has been serving as one of the most commonly used performance measures. However, for systems with analog inputs, the ultimate goal of the communication system is to minimize the overall input-output distortion. While BER plays the dominant role in distortion minimization, a communication system that minimizes the BER does not necessarily minimize the overall input-output distortion.

Therefore, it is desirable to provide an information transmission scheme that can achieve simultaneous BER and distortion minimization. The statements in this section merely provide background information related to the present disclosure and may not constitute prior art.

### SUMMARY

A method is provided for transmitting information in a data communication system. The method includes: receiving a codeword having a plurality of bits; mapping more significant bits of the codeword to bit locations of a symbol in a constellation with lower error probabilities, where the constellation represents a modulation scheme; modulating the symbol in accordance with the modulation scheme; and transmitting the symbol from a transmitter in the data communication system.

Further areas of applicability will become apparent from the description provided herein. It should be understood that the description and specific examples are intended for purposes of illustration only and are not intended to limit the scope of the present disclosure.

### DRAWINGS

FIG. 1 is a block diagram of an exemplary digital communication system;

FIG. 2 is a graph of a mapping of quantized values to the 16-QAM constellation;

FIG. 3 illustrates a one-dimensional 16-AM constellation;

FIG. 4 illustrates a method for transmitting information in a data communication system;

FIG. 5A is a graph of an asymmetric 16-QAM constellation;

FIG. 5B is a graph of a symmetric 16-QAM constellation with Gray codes;

FIGS. 6A and 6B are graphs illustrating performance results for different transmission schemes using coded and uncoded systems, respectively;

FIG. 7A illustrates a source consisting of two Gaussian distributed random processes; and

FIG. 7B is a graph depicting normalized MSE under different SNR levels for a uniform 4-AM versus the proposed source-aware 4-AM.

The drawings described herein are for illustration purposes only and are not intended to limit the scope of the present disclosure in any way.

### DETAILED DESCRIPTION

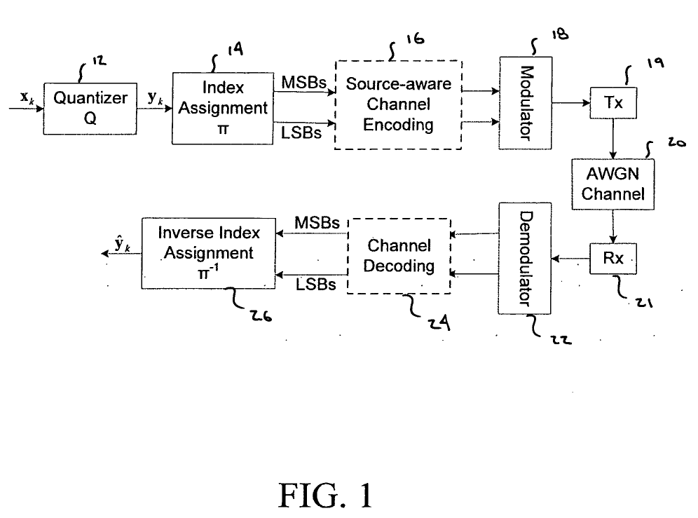

FIG. 1 illustrates an exemplary digital communication system with analog input. Let xₖ be the discrete-time analog input vector resulted from uniform sampling of a continuous signal x(t). xₖ is first fed into a quantizer (Q) 12, which is a mapping of n-dimensional Euclidean space Rⁿ to a finite set P ⊂ Rⁿ, given by Q:Rⁿ→P, where P={P₀, P₁, . . . , P_{M-1}} is the quantization codebook with Pᵢ ε Rⁿ for 0≦i≦M-1. Assume that the size of P is |P|=M=2^{m}, where m>0 is an integer. Let yₖ=Q(xₖ) denote the quantization value of xₖ, yₖ is coded into a binary sequence through an index assignment function (π) 14, and is then fed into a source-aware digital channel encoder 16 and a modulator 18, i.e., the most significant bits (MSB) and least significant bits (LSB) may be treated distinctly. Let ŷₖ denote the receiver output, which is an estimate of the quantization value yₖ, the averaged input-output distortion is then given by
D₀=E{d(xₖ, ŷₖ)}, (1)
where d:Rⁿ×Rⁿ→R is a non-negative function that measures the distance between two vectors in Rⁿ.

Consider the widely used mean-square distortion function d(x, y) ∥x−y∥². In this case, the optimal quantizer satisfies the well-known nearest neighbor and centroid conditions. The overall distortion D₀ can then be decomposed into two parts, namely, the distortion due to quantization noise, and the distortion due to channel noise, denoted as n_{q} and n_{c}, respectively. That is,

$${x}_{k} - {\hat{y}}_{k} = \underbrace{( {x}_{k} - {y}_{k} )}_{{n}_{q}} + \underbrace{( {y}_{k} - {\hat{y}}_{k} )}_{{n}_{c}}$$

When the quantizer satisfies the centroid condition, E{n_{q}}=0. Note that the quantization noise and the channel noise are independent, we have E{n_{q}n_{c}^{H}}=E{n_{c}n_{q}^{H}}=0. It then follows that

$$\begin{matrix}{D}_{0} = E \{ {‖ {n}_{q} ‖}^{2} \} + E \{ {‖ {n}_{c} ‖}^{2} \} \\ = E \{ {‖ {x}_{k} - {y}_{k} ‖}^{2} \} + E \{ {‖ {y}_{k} - {\hat{y}}_{k} ‖}^{2} \}\end{matrix} \qquad ( 2 )$$

When the quantizer is optimal, the distortion due to quantization error is minimized. Minimization of Dₒ is thus reduced to minimizing the distortion only due to the channel noise
D=E{d(yₖ, ŷₖ)} (3)
Joint source index assignment and constellation codeword design for minimum distortion is considered further.

First, we consider to minimize the distortion D=E{∥yₖ−ŷₖ∥²} through joint design of source index assignment and index mapping. Write yₖ as yₖ=ŷₖ+eₖ where yₖ, ŷₖ ε P={P₀, P₁, . . . P_{M-1}}, and eₖ is the estimation error. For 0≦i≦M-1, define Eᵢ={Pᵢ Pⱼ, 0≦j≦M-1}, it then follows that

$$\begin{matrix}D = E \{ {‖ {y}_{k} - {\hat{y}}_{k} ‖}^{2} \} \\ = {\sum }_{i = 0}^{M - 1} {\sum }_{j = 0}^{M - 1} {‖ {P}_{i} - {P}_{j} ‖}^{2} p ( {\hat{y}}_{k} = {P}_{j} \vert {y}_{k} = {P}_{i} ) p ( {y}_{k} = {P}_{i} ) \\ = {\sum }_{i = 0}^{M - 1} p ( {y}_{k} = {P}_{i} ) {\sum }_{{e}_{k} ∈ {E}_{i}} {‖ {e}_{k} ‖}^{2} p ( {e}_{k} ) .\end{matrix}$$

(4)
Here p(x) denotes the probability that x occurs.

For efficient transmission, each quantizer output yₖ is first coded to a binary sequence then mapped to a symbol in a constellation Ω. When the signal-to-noise ratio (SNR) is reasonably high, as it is for most useful communication systems, each transmitted symbol is more likely to be mistaken for one of its neighbors than for far more distant symbols. Therefore, to minimize the distortion D, the optimal index assignment and constellation codeword design should map the neighboring quantization vectors from the quantization codebook P to neighboring symbols in constellation Ω. More specifically, the optimal 1-1 mapping S:P→Ω should satisfy the following condition:
Let Pᵢ,Pⱼ,\tilde{P}ᵢ,\tilde{P}ⱼ ε P, then d(Pᵢ,Pⱼ)≦d(\tilde{P}ᵢ,\tilde{P}ⱼ) if and only if d(S(Pᵢ),S(Pⱼ))≦d(S(\tilde{P}ᵢ),S(\tilde{P}ⱼ)). C1
That is, ideally, an isomorphic mapping that reserves the geometric structure should exist between the quantization codebook P and the constellation Ω. When the quantizer is optimal, and the constellation is Gray coded, condition (C1) ensures the equivalence between minimizing the BER and minimizing the average distortion.

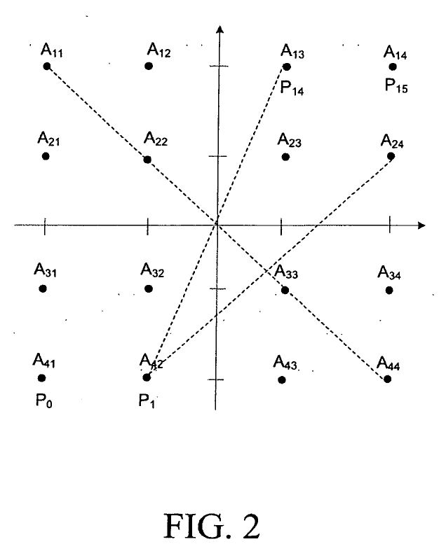

Next we look at the necessary conditions for the existence of S that satisfies (C1). First, assume that the size of the constellation |Ω|=|P|=M, and then look at the case when |Ω|<|P|. Start with systems equipped with scalar quantizers and two-dimensional constellations. Consider a system with a 4-bit uniform scalar quantizer and a 16-QAM constellation as shown in FIG. 2. Since P={P₀, P₁, . . . P₁₅} ⊂ R, without loss of generality, assume P₀<P₁< . . . <P₁₅. As can be seen, each Pᵢ has at most two nearest neighbors, but a symbol in a 16-QAM constellation can have as many as 4 nearest neighbors. It is then impossible to find an S:P→Ω that satisfies (C1).

In fact, assuming there is an S:P→Ω that satisfies (C1), then we should have

$$\begin{matrix}d ( S ( {P}_{0} ) , S ( {P}_{15} ) ) = {max}_{{x}_{1} , {x}_{2} ∈ Ω} d ( {x}_{1} , {x}_{2} ) , & ( 5 ) \\ d ( S ( {P}_{0} ) , S ( {P}_{1} ) ) = d ( S ( {P}_{14} ) , S ( {P}_{15} ) ) = {min}_{{x}_{1} , {x}_{3} ∈ Ω} d ( {x}_{1} , {x}_{2} ) , & ( 6 ) \\ d ( S ( {P}_{1} ) , S ( {P}_{14} ) ) \geq {max}_{{P}_{i} , {P}_{j} ∈ P} \{ d ( S ( {P}_{i} ) , S ( {P}_{j} ) ) \} , i , j \neq 0 , 1 , 14 , 15 & ( 7 )\end{matrix}$$

Without loss of generality, assume S(P₀)=A₄₁, S(P₁₅)=A₁₄, as illustrated in FIG. 2. Now consider the pair P₁ and P₁₄. For (6) to be satisfied, P₁ and P₁₄ should be mapped to the nearest neighbors of P₀ and P₁₅, respectively. Without loss of generality, assume S(P₁)=A₄₂. Since d(A₄₂, A₁₃)>d(A₄₂, A₂₄), according to (C1), we should have S(P₁₄)=A₁₃ However, this violates (7), since d(A₄₂, A₁₃)<(A₁₁ A₄₄) but A₁₁, A₄₄ will correspond to points from {Pᵢ, i≠0, 1, 14, 15}. This implies that, to satisfy (7), P₁ and P₁₄ should be mapped to the pair A_{II} and A₄₄. Clearly, this violates (6). Therefore, an S that satisfies (C1) does not exist. More generally, for systems utilizing scalar quantizer with codebook P and a symmetric (two-dimensional) rectangular or square constellation Ω with |Ω|=|P|=2^{m},m>1, there is no 1-1 mapping S:P→Ω that satisfies (C1).

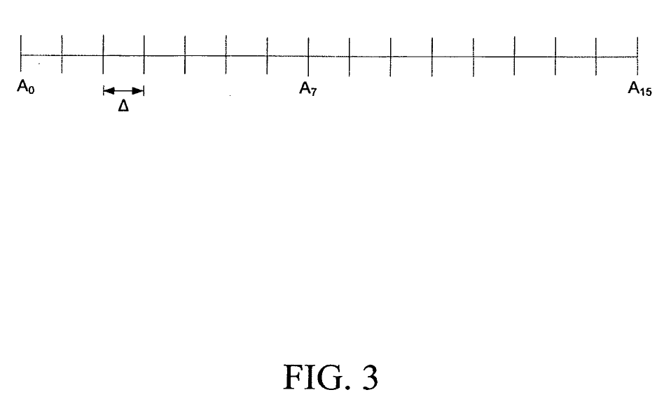

In contrast, for the 4-bit scalar quantizer discussed above, instead of 16-QAM, consider the one-dimensional constellation 16-AM with Gray code as shown in FIG. 3. Still denoting the constellation with Ω, clearly the 1-1 mapping S:P→Ω defined by S(Pᵢ)=Aᵢ, 0≦i≦15, satisfies (C1), and it minimizes the BER and the distortion D simultaneously. This one-dimensional case implies that simultaneous minimization of BER and distortion D essentially requires that there exists a 1-1 mapping S:P→Ω₀ which satisfies, condition (C1), where Ω₀ ⊂̅Ω is a real subset of Ω or Ω itself. This result provides another demonstration to the well known fact that: the essence to obtaining larger coding gain is to design codes in a subspace of signal space with higher dimensionality, as a larger minimum distance can be obtained with the same signal power. For example, two-dimensional constellation such as QAM would be a natural choice for two-dimensional vector quantizers. For multidimensional vector quantizers, multidimensional constellations would fit best. In the case when |Ω|<|P|, more than one constellation symbols are needed to represent one, quantization value. Again, the multidimensional signal constellation obtained from the Cartesian product, Ω^{N} should be exploited.

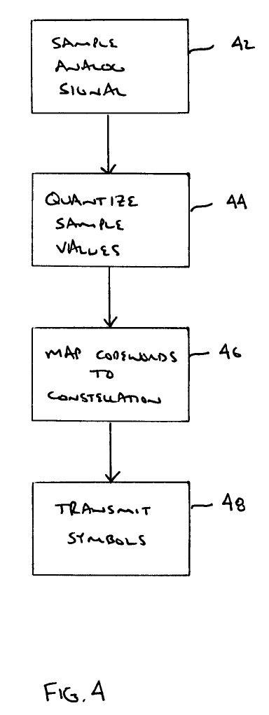

FIG. 4 illustrates this proposed method for transmitting information in a data communication system. Briefly, an incoming analog signal may be sampled and quantized into discrete signal values. Each quantized signal value is then coded into a codeword formed by a binary sequence. Codewords are in turn mapped to symbols of a constellation, where the constellation represent a modulation scheme for the codewords. Simultaneous minimization of bit error rate and distortion could be through constellation-aware source index assignment. Lastly, the modulation symbols may be transmitted in the data communication system. Although reference has been made to quadrature amplitude modulation, it is readily understood that the broader aspect of this disclosure are not limited to a particular modulation scheme.

Due to lack of a priori statistical information of the input signal, non-entropy coding is widely used for various sources in practice. That is, in each quantization codeword, some bits are more significant than other bits, and an error in a significant bit will result in larger distortion than that in a less significant bit. This universal existence of non-uniformity in source coding calls for non-uniform information transmission, also known as unequal error protection, in which the most significant bits have lower bit error-rates than other bits. In the following, we consider source-aware non-uniform transmission design along the line of joint source index assignment and constellation design.

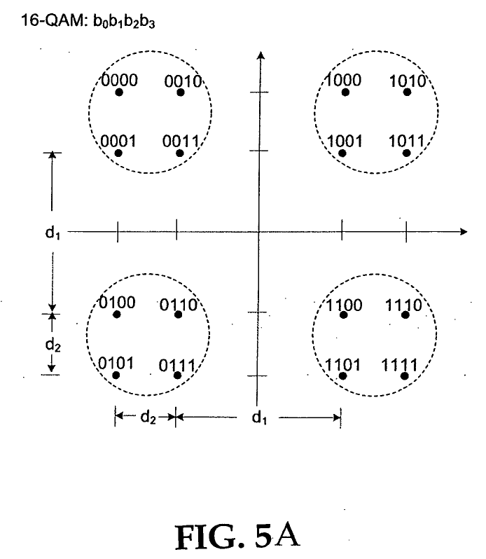

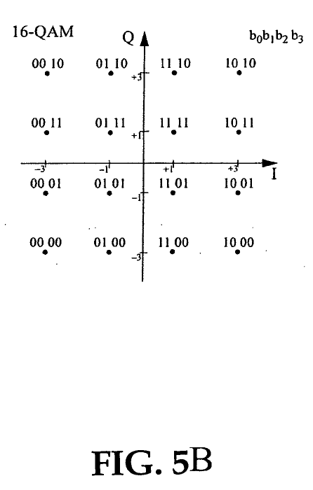

With the exception of BPSk and QPSK, non-uniformity exists in most constellations. Asymmetric constellations were originally developed for multiresolution (MR) broadcast in Digital HDTV. The asymmetric constellations were designed to provide more protection to the more significant bits by grouping bits into clouds leading by the most significant bits, and the minimum distance between the clouds is larger than the minimum distance between symbols within a cloud as shown in FIG. 5A.

For symmetric constellations, an unequal error protection scheme based on block partitioning is provided in “Multilevel coded modulation for unequal error protection and multistage decoding” by R. H. Morelos-Zaragoza et al., IEEE Trans. Commun., Vol 48, pp 204-213, February 2000, which is the generalization of the Ungerboeck's mapping by set partitioning. With block partitioning, the number of nearest neighbors is minimized for each bit level bᵢ. It turns out that the resulted codeword design coincide with that of the MR scheme with d₁=d₂. As can be seen, constellations resulted from either block partitioning or the MR scheme may no longer be Gray-coded.

Gray codes are developed to minimize the bit-error-rate, in which the nearest neighbors correspond to bit groups that differ by only one position. Here, we revisit the non-uniformity in constellations with Gray codes, and introduce a non-uniform transmission scheme based on Gray-coded constellations. In the following, we illustrate the idea through Gray coded 16-QAM constellation shown in FIG. 5B.

In 16-QAM, each codeword has the form b₀b₁b₂b₃ If we go through the 16 symbols in FIG. 5B, there are altogether 24 nearest neighbor bit changes, among which b₀ and b₂ each changes 4 times, and b₁ and b₃ each changes 8 times. Note that when channel probability error is sufficiently small, a bit error corresponding to each bit location bᵢ is most likely to occur when the nearest neighbor has a different value in that specific bit location, i.e., among neighboring pairs where a change occurs. Let Pₑ denote the error probability, then this implies that when SNR is reasonably high,

$${P}_{e} ( {b}_{0} ) = {P}_{e} ( {b}_{2} ) = \frac{1}{2} {P}_{e} ( {b}_{1} ) = \frac{1}{2} {P}_{e} ( {b}_{3} ) .$$

Accordingly, we propose to minimize the average distortion by exploiting the inherent non-uniformity in Gray-coded constellations, that is, to map the more significant bits from the source encoder to bit locations with lower error probability in constellations with Gray codes. For example, consider a 4-bit quantizer and a 16-QAM constellation as in FIG. 5B, the two MSBs will be mapped to b₀ and b₂, while the two LSBs be mapped to b₁ and b₃. This mapping function is preferably performed by the channel encoder 16 shown in FIG. 1.

This proposed approach may be summarized as follows. For a non-uniform source, a Grey-coded constellation is defined for the designated modulation scheme. Within the constellation, bit locations having a lower error probability are noted. The more significant bits are identified in the bit sequence received from the quantizer. Given a binary sequence from the source, the more significant bits in the binary sequence are then mapped to the bit locations having the lower error probability in the constellation. Lastly, the binary sequence is modulated in accordance with the constellation. While the above description has been provided with reference to a quadrature amplitude modulation scheme, it is readily understood that this approach is extendible to other types of the modulation schemes.

The proposed approach can be applied to both symmetric and asymmetric constellations. To illustrate the performance, we compare the proposed Gray-code based non-uniform transmission scheme with the block partitioning based approaches for both coded and uncoded systems (note that the MR scheme is only for asymmetric constellations and coincides with the block partitioning based method in the asymmetric case).

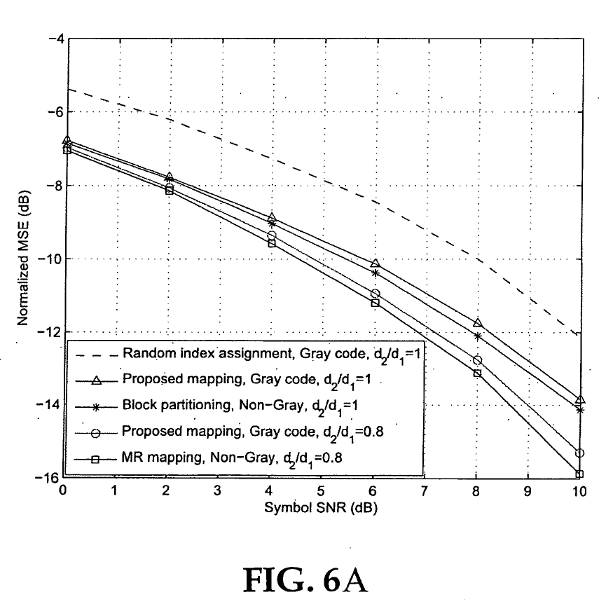

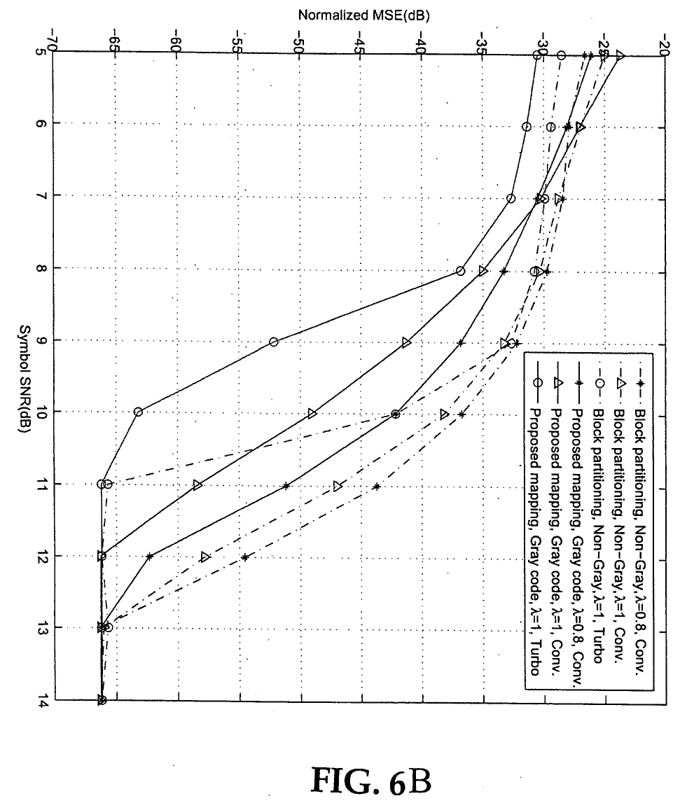

First, the source is assumed to be analog with the amplitude uniformly distributed within [0,100], quantized using a 12-bit uniform quantizer. We consider various 16-QAM constellations, both symmetric and asymmetric. First, each 12-bit quantization output b₀b_{1 . . .} b₁₁ is partitioned into three 4-bit strings: b₀b₁b₆b₇, b₂b₃b₈b₉, b₄b₅b₁₀b_{11,} then mapped to both symmetric and asymmetric 16-QAM constellations based on the block partitioning (BP) scheme or the proposed Gray-code based non-uniform transmission scheme. By random index assignment, we mean that no distinction is made on MSBs and LSBs, and the strings are mapped to the Gray coded constellation based on their original bit arrangements b₀b₁b₂b_{3,} b₄b₅b₆b₇, b₈b₉b₁₀b_{11.} The result is shown in FIG. 6A.

In another example, impact of channel coding is investigated for both systematic and non-systematic coding schemes. Using the same source as in the example above, a 10-bit uniform quantizer is connected with a source-aware channel encoder, for which the first 4 MSBs are fed to a rate 1/3 convolutional (or Turbo) encoder and the rest 6 bits are fed to a rate 1/2 convolutional (or Turbo) encoder, respectively. The channel coding output is then mapped to 16-QAM constellations non-uniformly based on the block partitioning approach and the proposed mapping scheme. The result is shown in FIG. 6B.

As demonstrated by the simulation results, while the proposed approach has comparable performance with existing unequal error protection methods for uncoded systems (i.e. when there is no channel coding), the Gray-code based non-uniform transmission outperforms the non-Gray coded methods (i.e., the MR method and the block partitioning based approach) with big margins when channel coding is involved. The underlying arguments are: (i) channel coding may change the geometric structure of the uncoded symbols; and (ii) when SNR is reasonably high, BER of the more significant bits vanishes, and BER of the less significant bits dominates the overall distortion, and hence Gray coded constellations result in much better performance.

Constellation design has largely been separated from quantizer design in the past. However, we further consider joint quantizer-constellation design for minimum distortion. Following our discussions, we propose to incorporate the source information reflected in optimal quantizer design into constellation design. Note that the optimal quantizers minimize the average distortion between the original sampled values and the quantization values, when considering memoryless AWGN channels, optimal quantizers can be exploited directly for constellation design. We illustrate this idea through the following example.

Consider a non-uniform scalar quantizer with four possible quantization values. Assuming the quantization code book is P={P₁, . . . P₄}, where Pᵢ<Pᵢ+₁ for i=1, 2, 3 and each Pᵢ occurs with probability p(Pᵢ)=Pᵢ for i=1, . . . , 4. Define Dᵢⱼ=|P-Pⱼ|². Along the lines of Lemma 1, we consider the design of a 4-AM constellation Ω={A₁, . . . ,_{A}_{₄}} and assume that the 1-1 map S:Ω→P is designed to satisfy condition (C1). We further assume that the quantizer is optimal, that is, it satisfies the nearest neighbor rule and the centroid criterion. Define dᵢⱼ=|Pᵢ-Pⱼ| for i, j=1, . . . ,4, dᵢ=|Aᵢ-Aᵢ+₁| for i=1, 2, 3, and let Dᵢ be the average distortion corresponding to symbol Aᵢ for i=1, . . . ,4. Consider a memoryless AWGN channel, for which the noise is zero mean and with variance σ², then we have

$${D}_{1} = {d}_{12}^{2} [ Q ( \frac{{d}_{1}}{2 σ} ) - Q ( \frac{2 {d}_{1} + {d}_{2}}{2 σ} ) ] + {d}_{13}^{2} [ Q ( \frac{2 {d}_{1} + {d}_{2}}{2 σ} ) - Q ( \frac{2 {d}_{1} + 2 {d}_{2} + {d}_{3}}{2 σ} ) ] + {d}_{14}^{2} Q ( \frac{2 {d}_{1} + 2 {d}_{2} + {d}_{3}}{2 σ} )$$

$${D}_{2} = {d}_{12}^{2} Q ( \frac{{d}_{1}}{2 σ} ) + {d}_{23}^{2} [ Q ( \frac{{d}_{2}}{2 σ} ) - Q ( \frac{2 {d}_{2} + {d}_{3}}{2 σ} ) ] + {d}_{24}^{2} Q ( \frac{2 {d}_{2} + {d}_{3}}{2 σ} )$$

$${D}_{3} = {d}_{13}^{2} Q ( \frac{{d}_{1} + 2 {d}_{2}}{2 σ} ) + {d}_{23}^{2} [ Q ( \frac{{d}_{2}}{2 σ} ) - Q ( \frac{2 {d}_{2} + {d}_{1}}{2 σ} ) ] + {d}_{34}^{2} Q ( \frac{{d}_{3}}{2 σ} )$$

$${D}_{4} = {d}_{34}^{2} [ Q ( \frac{{d}_{3}}{2 σ} ) - Q ( \frac{{d}_{2} + 2 {d}_{3}}{2 σ} ) ] + {d}_{24}^{2} [ Q ( \frac{2 {d}_{2} + 2 {d}_{3}}{2 σ} ) - Q ( \frac{{d}_{1} + 2 {d}_{2} + 2 {d}_{3}}{2 σ} ) ] + {d}_{14}^{2} Q ( \frac{{d}_{1} + 2 {d}_{2} + {d}_{3}}{2 σ} )$$

where

$$Q ( x ) = \frac{1}{\sqrt{2 π}} {\int }_{x}^{∞} {ⅇ}^{- {t}^{2} / 2} ⅆ t .$$

The overall average distortion can be written as

$$D = {\sum }_{i = 1}^{4} {p}_{i} {D}_{i} \qquad ( 8 )$$

Define

$${γ}_{1} = \frac{{d}_{1}}{σ} , {γ}_{2} = \frac{{d}_{2}}{{d}_{1}} , {γ}_{{3}^{′}} = \frac{{d}_{3}}{{d}_{1}} ,$$

the problem of optimal constellation design for, minimum average distortion is reduced to finding γ₁, γ₂, γ₃ such that D is minimized, subjected to a power constraint, that is

$${min}_{{γ}_{1} , {γ}_{2} , {γ}_{3}} D subjected to {P}_{s} \leq C \qquad ( 9 )$$

where Pₛ is the average symbol power and C is a constant. The method used in this example can be extended directly to more general cases. We illustrate the proposed approach through an example.

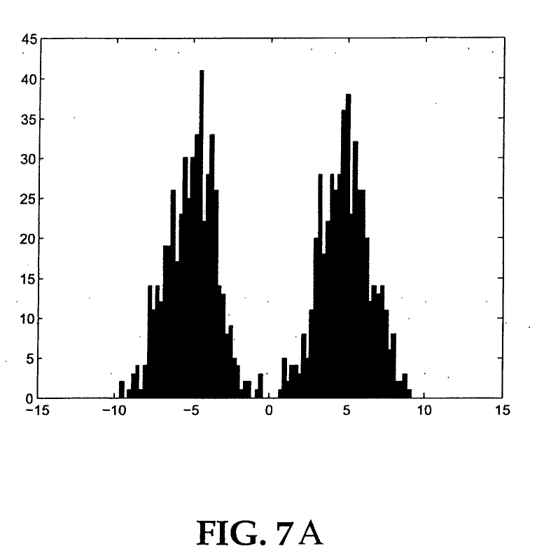

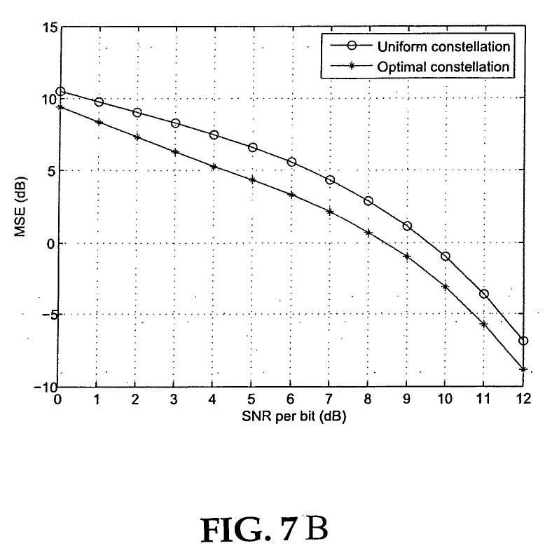

Consider a source consists of two Gaussian distributed random processes centered at ±5 with variance σ²=(5/3)², as shown in FIG. 7A. Using a 4-level optimal quantizer with codebook P={−6.40, −3.86, 3.69, 6.2}, normalized MSE under different SNR levels is shown in FIG. 7B for both uniform 4-AM and the proposed source-aware 4-AM.

From the simulation result, it can be seen that while symmetric constellations are optimal for uniformly distributed sources, asymmetric constellations reduce the average distortion significantly for sources that require non-uniform quantization. Compared with the asymmetric constellations originally designed for multiresolution broadcasting, the proposed joint quantizer-constellation design scheme generalizes the concept of non-uniform constellation design from the perspective of joint source-channel coding.

In this disclosure, we studied joint optimization of source index assignment and modulation design for overall input-output distortion minimizations in communication systems. Taking a joint source-channel coding perspective, distortion minimization was carried out through Gray-code based non-uniform mapping and joint quantizer-constellation design. More specifically, our contributions can be summarized as:
We focused on distortion minimization for any wireless systems with analog input. Our discussion on simultaneous minimization of BER and average input-output distortion provides an interface between the optimal system design for minimum distortion and the traditional system design focused on BER minimization.
We proposed a novel non-uniform transmission scheme based on Gray-coded constellations. This design makes it possible for simultaneous minimization of distortion and BER. At the same time, the proposed approach outperforms existing unequal error protection approaches with big margins when channel coding is involved. Channel coding is widely used in almost all communication systems. Therefore, this approach can be applied to improve the power and spectral efficiency of virtually any the digital communication systems with analog inputs, particularly for systems with tight power constraints such as wireless sensor networks and space communications.
We also proposed a novel method on optimal constellation design for minimum distortion, by incorporating the source information reflected in optimal quantizer design into constellation design. This scheme generalized the concept of non-uniform constellation design and is particularly attractive for systems with non-uniform sources.

The description in this disclosure is exemplary in nature and is not intended to limit the present disclosure, application, or uses.

What is claimed is:

1. A method for transmitting information in a data communication system, comprising:
receiving a codeword having a plurality of bits;
mapping more significant bits of the codeword to bit locations of a symbol in a constellation with lower error probabilities, where the constellation represents a modulation scheme;
modulating the symbol in accordance with the modulation scheme; and
transmitting the symbol from a transmitter in the data communication system.

2. The method of claim 1 further comprises receiving an analog input signal, sampling the analog input signal to generate a plurality of sample values, and quantizing each sample value to a codeword in accordance with a quantization codebook.

3. The method of claim 1 further comprises selecting a constellation having same dimensionality as the quantization codebook.

4. The method of claim 1 wherein the symbols of the constellation are Gray coded.

5. The method of claim 1 further comprised modulating the symbol in accordance with a quadrature amplitude modulation scheme.

6. The method of claim 1 further comprises designing the constellation based in part on an attribute of the analog input signal.

7. The method of claim 1 further comprises employing a symmetric constellation when the analog input signal is symmetric.

8. The method of claim 1 further comprises employing an asymmetric constellation when the analog input signal is asymmetric.

9. The method of claim 1 further comprises designing the constellation based in part on power constraints.

10. A method for transmitting information in a data communication system, comprising:
sampling an incoming analog signal;
quantizing sample values of the analog signal into codewords in accordance with a quantization codebook;
selecting a constellation having Grey coded symbols, where the constellation represents a modulation scheme for the codewords; and
transmitting the modulated codewords.

11. The method of claim 10 further comprises selecting a constellation having same dimensionality as the quantization codebook.

12. The method of claim 10 further comprises mapping more significant bits of each codeword to bit locations of a symbol in a constellation with lower error probabilities.

13. The method of claim 10 further comprises selecting the constellation based in part on an attribute of the analog signal.

14. The method of claim 10 further comprises selecting a symmetric constellation for an analog signal having a uniformly distributed amplitude.

15. The method of claim 10 further comprises selecting an asymmetric constellation for an analog signal having a non-uniformly distributed amplitude.

16. An apparatus for transmitting data in a data communication system, comprising:
a quantizer adapted to receive an analog input signal and operable to translate each sample value of the analog signal to a codeword;
an encoder adapted to receive codewords from the quantizer and operable to map more significant bits of each codeword to bit locations of a symbol in a constellation with lower error probabilities, where the constellation represents a modulation scheme;
a modulator adapted to receive symbols from the encoder and modulate the symbols in accordance with the modulation scheme; and
a transmitter adapted to receive modulate symbols from the modulator and operable to transmit the modulated symbols through a data communication system.

17. The apparatus of claim 16 wherein the constellation has same dimensionality as a quantization codebook employed by the quantizer.

18. The apparatus of claim 16 wherein the constellation having Grey coded symbols.

19. A method for transmitting information in a data communication system, comprising:
sampling an incoming analog signal;
quantizing sample values of the analog signal into codewords in accordance with a quantization codebook;
selecting a constellation having same dimensionality as the quantization codebook and modulating the codewords in accordance with the constellation, where the constellation represents a modulation scheme for the codewords; and
transmitting the modulated codewords.

20. The method of claim 19 further comprises selecting a constellation having Gray coded symbols.

21. The method of claim 19 further comprises mapping more significant bits of each codeword to bit locations of a symbol in a constellation with lower error probabilities.

22. The method of claim 19 further comprises selecting the constellation based in part on an attribute of the analog signal.

23. The method of claim 19 further comprises selecting a symmetric constellation for an analog signal having a uniformly distributed amplitude.

24. The method of claim 19 further comprises selecting an asymmetric constellation for an analog signal having a non-uniformly distributed amplitude.
